(19) United States
(12) Patent Application Publication
(10) Pub. No.: US 2015/0068596 A1
(43) Pub. Date: Mar. 12, 2015

(54) SOLAR CELL MODULE AND METHOD FOR MANUFACTURING SOLAR CELL MODULE

(71) Applicant: SANYO Electric Co., Ltd., Osaka (JP)

(72) Inventors: Yoshikazu IBARA, Gifu (JP); Nozomu TOKUOKA, Osaka (JP); Hiroyuki KASE, Shiga (JP)

(21) Appl. No.: 14/539,057

(22) Filed: Nov. 12, 2014

Related U.S. Application Data
(63) Continuation of application No. PCT/JP2012/066667, filed on Jun. 29, 2012.

(51) Int. Cl. H01L 31/0224

(52) U.S. Cl. CPC H01L 31/022433
USPC 136/256

(57) ABSTRACT

A solar cell module is provided with: a photoelectric conversion section having a substrate; collecting electrodes, which are disposed on the photoelectric conversion section; adhesive layers disposed on the collecting electrodes; and wiring material pieces respectively connected to the collecting electrodes with the adhesive layers therebetween. In the longitudinal direction of the collecting electrodes, the collecting electrodes respectively have end portions formed thicker than the center portions, and in the longitudinal direction of the collecting electrodes, the adhesive layers respectively have potions corresponding to the center portions of the collecting electrodes formed thicker than adhesive layer portions corresponding to the end portions of the collecting electrodes.

### CROSS-REFERENCE TO RELATED APPLICATIONS

The present application is a continuation under 35 U.S.C. §120 of PCT/JP2012/066667, filed Jun. 29, 2012, which is incorporated herein by reference.

### TECHNICAL FIELD

The present invention relates to a solar cell module in which solar cells are connected by wiring material, and a method for manufacturing the solar cell module.

### BACKGROUND ART

In addition to a vapor deposition method, a sputtering method, and screen printing that prints a conductive paste, a plating method is also used as a method for forming electrodes of a solar cell.

For example, in Patent Literature 1, as a method for manufacturing a solar cell, a method is described in which seed metal is disposed on a silicon substrate, and the seed metal is used to form a surface electrode and a rear electrode by electrolytic plating.

### CITATION LIST

### Patent Literature

### Patent Literature 1

Japanese Patent Laid-Open Publication No. 2000-294819

### SUMMARY OF INVENTION

### Technical Problem

An object of the present invention is to provide a solar cell module with superior performance.

### Solution to Problem

A solar cell module according to the present invention includes: a photoelectric conversion section; a collecting electrode disposed on the photoelectric conversion section; an adhesive layer disposed on the collecting electrode; and wiring material that is connected to the collecting electrode with the adhesive layer therebetween; wherein: in the collecting electrode, a thickness of an end portion of the collecting electrode is formed thicker than a center portion thereof in a longitudinal direction of the collecting electrode; and in the adhesive layer, a thickness of a portion corresponding to the center portion of the collecting electrode is formed thicker than a thickness of a portion corresponding to the end portion of the collecting electrode in the longitudinal direction of the collecting electrode.

A method for manufacturing a solar cell module according to the present invention is a method that forms a collecting electrode on a photoelectric conversion section, and connects wiring material to the collecting electrode with an adhesive layer therebetween, wherein: a power supply section is provided at both end portions of the photoelectric conversion section in a longitudinal direction of the collecting electrode, and the collecting electrode is formed by electrolytic plating in a formation region for the collecting electrode on the photoelectric conversion section; an adhesive is coated on the collecting electrode to form an adhesive layer; the collecting electrode and the wiring material are connected by pressing the wiring material from above the adhesive layer; a thickness of an end portion of the collecting electrode is formed thicker than a thickness of a center portion thereof in the longitudinal direction of the collecting electrode by electrolytic plating; and in the adhesive layer, a thickness of a portion that corresponds to the center portion of the collecting electrode is formed thicker than a thickness of a portion thereof that corresponds to the end portion of the collecting electrode in the longitudinal direction of the collecting electrode by pressing the wiring material against the collecting electrode.

### Advantageous Effects of Invention

The present invention provides a solar cell module with superior performance by means of the above described configuration.

### BRIEF DESCRIPTION OF DRAWINGS

FIGS. 1(a) and (b) are a plan view and a sectional view of a solar cell module of an embodiment according to the present invention.

FIG. 2 is a flowchart showing procedures of a method for manufacturing a solar cell module of the embodiment according to the present invention.

FIGS. 3(a) and (b) are views illustrating a substrate with a plating mask in a procedure described in FIG. 2.

FIG. 4 is a view illustrating electrolytic plating that is performed next after the procedure illustrated in FIGS. 3(a) and (b).

FIG. 5 is a view illustrating a solar cell having a collecting electrode that is formed by the electrolytic plating illustrated in FIG. 4.

FIG. 6 FIG. 6 is a view illustrating adhesive layers and wiring materials that are prepared next after the procedure illustrated in FIG. 5.

FIG. 7 is a view illustrating a process that crimps the wiring materials through the adhesive layers onto a solar cell having collecting electrodes.

FIG. 8 is a view illustrating a solar cell module that is formed by the crimping process illustrated in FIG. 7.

FIGS. 9(a) and (b1) to (b3) are a plan view and sectional views of a solar cell formed by performing electrolytic plating using a plating mask in the embodiment according to the present invention.

FIG. 10 FIG. 10 is a flowchart showing procedures of a plating process in the embodiment according to the present invention.

FIG. 11 illustrates a textured substrate in a procedure described in FIG. 10.

FIG. 12 FIG. 12 is a view illustrating a matte plated layer that is formed next after the procedure illustrated in FIG. 11.

FIG. 13 is a view illustrating a bright plated layer that is formed next after the procedure illustrated in FIG. 12.

FIG. 14 is a view illustrating an action of a solar cell module that uses the solar cell formed by the process described in FIG. 10.

### DESCRIPTION OF EMBODIMENTS

Hereunder, an embodiment of the present invention is described in detail using the accompanying drawing. In the following description, like constituent elements are denoted by like reference numerals in all of the drawings, and duplicated descriptions are omitted. Further, in the description in the text, previously mentioned reference numerals are used where necessary.

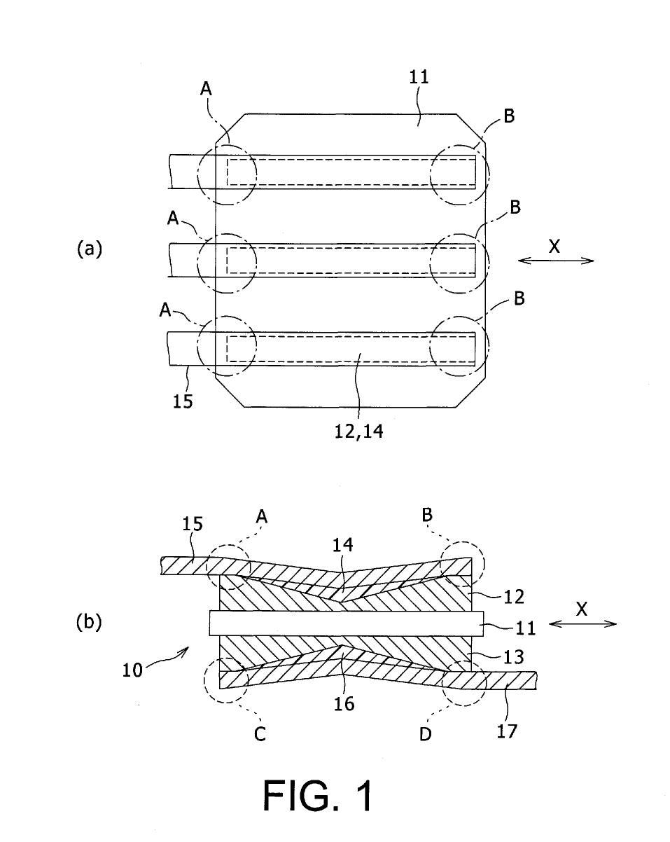

FIGS. 1(a) and (b) illustrate a solar cell module 10, in which (a) is a plan view and (b) is a sectional view. The solar cell module 10 includes a photoelectric conversion section 11, collecting electrodes 12 and 13 that are formed on both sides of the photoelectric conversion section 11, wiring material 15 that is connected to the collecting electrode 12 with an adhesive layer 14 therebetween, and wiring material 17 that is connected to the collecting electrode 13 with an adhesive layer 16 therebetween.

The photoelectric conversion section 11 includes, as main surfaces, a light-receiving surface that is a face on which light from outside is incident, and a rear surface that is a face on the opposite side to the light-receiving surface. In FIG. 1(b), the collecting electrode 12 side is the light-receiving surface, and the collecting electrode 13 side is the rear surface. Although the light-receiving surface and the rear surface are illustrated as having the same structure in FIG. 1(b), there may be a difference in sectional views between the light-receiving surface and the rear surface depending on the specifications of the photoelectric conversion section 11.

The photoelectric conversion section 11 generates photogenerated carriers that are electron-hole pairs by receiving light such as the light of the sun. The photoelectric conversion section 11, for example, has a substrate made of a semiconductor material such as crystalline silicon (c-Si), gallium arsenide (GaAs), or indium phosphide (InP). The structure of the photoelectric conversion section 11 is a p-n junction in a broad sense. For example, a heterojunction between an n-type single-crystal silicon substrate and amorphous silicon can be used. In such a case, a structure can be adopted in which an i-type amorphous silicon layer, a p-type amorphous silicon layer doped with boron (B) or the like, and a transparent conductive film (TCO) made of a translucent conductive oxide such as indium oxide (In₂O₃) are laminated on a light-receiving surface side of the substrate, while an i-type amorphous silicon layer, an n-type amorphous silicon layer doped with phosphorus (P) or the like, and a transparent conductive film are laminated on a rear surface side of the substrate.

As long as the photoelectric conversion section 11 has a function that converts light such as sunlight to electricity, a structure other than the structure described above may also be adopted. For example, a structure may be adopted that includes a p-type polycrystalline silicon substrate, an n-type diffusion layer that is formed on the light-receiving surface side thereof, and an aluminum metal film that is formed on the rear surface side thereof.

The collecting electrodes 12 and 13 are electrode layers that are formed by a plating method on the light-receiving surface and the rear surface of the photoelectric conversion section 11, respectively, and are electrically connected to the photoelectric conversion section 11. Because the collecting electrodes 12 and 13 are formed by a plating method, the thickness of the collecting electrodes 12 and 13 at end portions in an X direction of the photoelectric conversion section 11 is thicker than the thickness of the collecting electrodes 12 and 13 at the center portion of the photoelectric conversion section 11. In this case, as shown in FIGS. 1(a) and (b), the X direction is a longitudinal direction in which the collecting electrodes 12 and 13 extend. In FIG. 1(b), in the X direction, the thickness of the collecting electrodes 12 and 13 is shown as being thicker at end portions A and B of the light-receiving surface on the photoelectric conversion section 11 and at end portions C and D of the rear surface. Note that in this case, a difference between the thicknesses of the end portions and the center portions of the collecting electrodes 12 and 13 is shown in an exaggerated form. The term “end portions of the collecting electrodes 12 and 13 in the X direction” includes the vicinity of peripheral edge portions of the photoelectric conversion section 11, and not only ends on the photoelectric conversion section 11 in the X direction in a strict sense.

The wiring material 15 on the light-receiving surface side is a conductive material that is pressed against the photoelectric conversion section 11 through the adhesive layer 14 to be mechanically and electrically connected to the collecting electrode 12.

The wiring material 15 is a thin plate that is composed of a metal conductive material such as copper. Wiring material having a twisted-wire shape can also be used instead of a thin plate. Besides copper, it is also possible to use silver, aluminum, nickel, tin, gold or alloys of these metals as the conductive material. Note that although in FIG. 1(b) an end face of the wiring material 15 and an end face of the collecting electrode 12 are aligned, this is an illustration of one example, and naturally the wiring material 15 can be set so as to be longer than the collecting electrode 12 to a certain extent.

The adhesive layer 14 is arranged between the collecting electrode 12 and the wiring material 15, and is a layer of resin adhesive that mechanically and electrically connects the collecting electrode 12 and the wiring material 17 as a result of crimping. The adhesive layer 14 is preferably an elastic and contractile material. A thermosetting resin adhesive layer that is acryl-based, highly flexible polyurethane-based, or epoxy-based can be used as the adhesive layer 14. The resin adhesive layer may be a liquefied layer or may be a resin adhesive sheet in a semi-cured state. Hereunder, the description is continued on the assumption that a resin adhesive sheet is used as the adhesive layer 14.

Preferably, conductive particles are included in the adhesive layer 14. In such a case, nickel, silver, gold-coated nickel, tin-plated copper and the like can be used as the conductive particles. When using an insulating resin adhesive layer that does not include conductive particles, a configuration is adopted in which either one of, or both of, the mutually opposing faces of the wiring material 15 and the collecting electrode 12 are rendered uneven, and the insulating resin is appropriately removed from between the wiring material 15 and the collecting electrode 12 to electrically connect the wiring material 15 and the collecting electrode 12.

Although originally the adhesive layer 14 has an even thickness, the thickness thereof at the end portions of the photoelectric conversion section 11 and the thickness at the center portion become uneven during the process in which the wiring material 15 is pressed against the photoelectric conversion section 11. That is, since the thickness of the collecting electrode 12 is thick at the end portions A and B of the photoelectric conversion section 11 and the thickness of the collecting electrode 12 is thin at the center portion of the photoelectric conversion section 11, when the wiring material 15 is pressed through the adhesive layer 14, a pressing force with respect to the adhesive layer 14 is liable to rise at the end portions A and B at which the collecting electrode 12 projects more, in comparison to the center portion. Consequently, the adhesive layer 14 is more liable to be removed at the end portions A and B of the collecting electrode 12 than at the center portion, and the thickness thereof becomes thinner at the end portions A and B and becomes thicker at the center portion.

Similarly, the wiring material 17 on the rear surface side is a conductive material that is pressed against the photoelectric conversion section 11 through the adhesive layer 16 to be mechanically and electrically connected to the collecting electrode 13. The material of the wiring material 17 is the same as that of the wiring material 15. The material of the adhesive layer 16 is the same as that of the adhesive layer 14. On the rear surface also, similarly to the light-receiving surface side, the thickness of the adhesive layer 16 is thinner at the end portions C and D and thicker at the center portion.

Thus, in the X direction, the thickness of the respective adhesive layers 14 and 16 is thinner at portions corresponding to the end portions A, B, C and D at which the thickness of the collecting electrodes 12 and 13 is thick, and the thickness of the respective adhesive layers 14 and 16 is thicker at a portion corresponding to the center portion at which the thickness of the collecting electrodes 12 and 13 is thin. Therefore, a structure can be formed in which mechanical joints between the wiring materials 15 and 17 and the collecting electrodes 12 and 13 are strong and the electrical resistance is low at the end portions on the photoelectric conversion section 11 at which current crowding is liable to arise in the wiring materials 15 and 17. The reason that current crowding is liable to arise at the portions of the wiring materials 15 and 17 that are at the end portions of the photoelectric conversion section 11 is as follows. Although currents that flow through the wiring materials 15 and 17 separate in all directions at the center portion of the photoelectric conversion section 11, a state is entered in which all the currents are gathered at the end portions of the photoelectric conversion section 11. Consequently, the current density is high at the portions of the wiring materials 15 and 17 at the end portions of the photoelectric conversion section 11 and current crowding occurs.

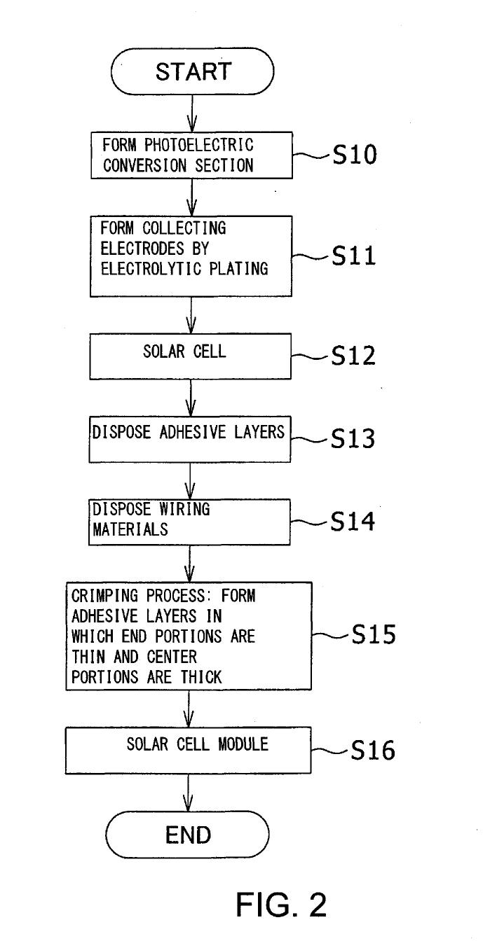

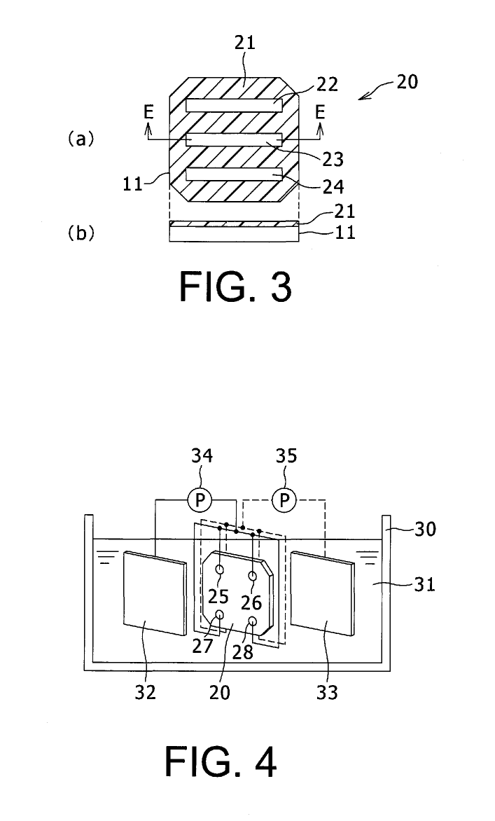

FIG. 2 is a flowchart showing procedures of a method for manufacturing the solar cell module 10 having the above described configuration. FIG. 3 to FIG. 8 are views that illustrate the manner of the procedures described in FIG. 2.

First, the photoelectric conversion section 11 that has a substrate is prepared (S10). Next, a plating mask is disposed on the photoelectric conversion section 11 to prepare for the subsequent electrolytic plating. FIGS. 3(a) and (b) illustrate a substrate with a plating mask 20, in which (a) is a plan view and (b) is a side view. The side view in FIG. 3(b) is a view along a line E-E in the plan view in FIG. 3(a).

In this case, a resist having opening sections 22, 23 and 24 for forming a collecting electrode is provided as a plating mask 21 on the photoelectric conversion section 11. The opening sections 22 to 24 are provided on each of the light-receiving surface side and the rear surface side of the photoelectric conversion section 11. Although the opening sections 22 to 24 have a rectangular shape, naturally the opening sections 22 to 24 may also have a shape other than a rectangular shape. The number of opening sections may also be other than three. Although the shape of the opening sections 22 to 24 on the light-receiving surface side and the shape of the opening sections on the rear surface are the same, naturally the shapes and numbers of the opening sections on the respective sides may be different to each other.

To form the plating mask 21 on the photoelectric conversion section 11, a method can be used in which a photosensitive resist is coated on the photoelectric conversion section 11, and the resist at the portions for the opening sections 22 to 24 is removed by performing selective exposure and development. Besides the aforementioned method, a method may also be adopted in which a mask layer having the opening sections 22 to 24 is printed on the photoelectric conversion section 11 by screen printing. Thus, the substrate with a plating mask 20 is obtained.

Returning again to FIG. 2, next, collecting electrodes are formed by electrolytic plating using the substrate with a plating mask 20 (S11). FIG. 4 is a view illustrating the manner in which the electrolytic plating is performed. The electrolytic plating is performed by the following procedure.

Power supply terminals for plating 25, 26, 27 and 28 are connected to the substrate with a plating mask 20. The power supply terminals 25 and 28 are also connected to the rear surface side, and not only to the light-receiving surface side.

Although omitted from the illustration in FIGS. 3(a) and (b), open holes for connecting the power supply terminals 25 to 28 to the substrate with a plating mask 20 are provided near the end portions in the X direction of the photoelectric conversion section 11 in the plating mask 21. Since the formation regions of the collecting electrode 12 are the opening sections 22 to 24, the power supply terminals 25 to 28 are connected at positions that are further to the end portion side than the opening sections 22 to 24. Thus, the power supply terminals 25 to 28 are electrically connected to the photoelectric conversion section using the open holes with respect to which the plating mask 21 of the substrate with a plating mask 20 is not applied. Note that a configuration may also be adopted in which a seed metal layer is provided for plating, and the power supply terminals 25 to 28 are electrically connected to the seed metal layer.

The power supply terminals 25 to 28 are connected to the light-receiving surface side and the rear surface side, respectively, of the substrate with a plating mask 20, and a predetermined plating solution 31 is filled in a plating bath 30. Cyanide-based and non-cyanide-based solutions containing ions of the plating metal are available as the predetermined plating solution 31, and a non-cyanide-based solution is preferable from a safety aspect. The non-cyanide-based solution may be any of a non-cyanide-based neutral type, a non-cyanide-based weak acidic type, a non-cyanide-based acidic type, a non-cyanide-based weak alkaline type, and a non-cyanide-based alkaline type. Gold, silver, copper, nickel, palladium, platinum or the like may be used as the plating metal. In the case of copper plating, copper sulfate, copper pyrophosphate, copper cyanide or the like is used, while in the case of nickel plating, nickel chloride, Watt's nickel, nickel sulfamate or the like is used.

Further, anode plates 32 and 33 made of the same material as the plating metal are prepared. The anode plates 32 and 33 are for plating the light-receiving surface side and plating the rear surface side of the substrate with a plating mask 20, respectively. Lead lines are connected from each of the power supply terminals 25 to 28 on the light-receiving surface side of the substrate with a plating mask 20, and the four leader lines are put together to form a single cathode terminal on the light-receiving surface side. A leader line is also connected to an end portion of the anode plate 32 to form an anode terminal on the light-receiving surface side. Similarly, although not illustrated in FIG. 4, a leader line is connected from each of the four power supply terminals on the rear surface side of the substrate with a plating mask 20, and the four leader lines are put together to form a single cathode terminal on the rear surface side. A leader line is also connected to an end portion of the anode plate 33 to form an anode terminal on the rear surface side.

The anode plate 32 connected to the anode terminal on the light-receiving surface side, the anode plate 33 connected to the anode terminal on the rear surface side, and the substrate with a plating mask 20 connected to the cathode terminal on the light-receiving surface side and the cathode terminal on the rear surface side are immersed in the plating solution 31. With respect to the arrangement of the anode plates 32 and 33 and the substrate with a plating mask 20, as shown in FIG. 4, a substrate with a plating mask 20 is arranged between the anode plates 32 and 33 so that the light-receiving surface of the substrate with a plating mask 20 faces the anode plate 32, and the rear surface of the substrate with a plating mask 20 faces the anode plate 33. The clearance between the anode plate 32 and the light-receiving surface of the substrate with a plating mask 20 is set to be the same as a clearance between the anode plate 33 and the rear surface of the substrate with a plating mask 20. These clearances are one of the plating conditions, and can be set to optimal value by experimentation or the like.

A plating power source 34 for the light-receiving surface side is connected between the anode terminal and cathode terminal on the light-receiving surface side, and a plating power source 35 for the rear surface side is connected between the anode terminal and cathode terminal on the rear surface side. Ions of the plating metal contained in the plating solution 31 move when a current is made to flow between the anode terminal and cathode terminal on the light-receiving surface side from the plating power source 34, and the plating metal deposits on the opening sections 22 to 24 on the light-receiving surface side of the substrate with a plating mask 20. Similarly, ions of the plating metal contained in the plating solution 31 move when a current is made to flow between the anode terminal and cathode terminal on the rear surface side from the plating power source 35, and the plating metal deposits on the opening sections 22 to 24 on the rear surface side of the substrate with a plating mask 20. Thus, electrolytic plating with respect to the substrate with a plating mask 20 is performed.

The thickness of a metal layer that deposits is the plating thickness. The plating thickness is determined by the size of a charge amount per unit area in the plating process. Since a charge amount is represented by (current value×time), if the period of time is the same, the plating thickness increases as the current value increases. According to the present embodiment, the conditions for the electrolytic plating, such as the positions of the power supply terminals 25 to 28 and the charge amount and the like, are set so that the plating thickness of the collecting electrodes 12 and 13 is thicker at the end portions than at the center portion in the X direction of the photoelectric conversion section 11.

After predetermined electrolytic plating has been performed with respect to the substrate with a plating mask 20, operation of the plating power sources 34 and 35 is stopped. The substrate with a plating mask 20 with respect to which the electrolytic plating was performed is then lifted up from the plating solution 31, and after being suitably washed, the power supply terminals 25 to 28 on the light-receiving surface side and the power supply terminals on the rear surface side are detached. The plating mask 21 is then removed. An applicable solvent can be used to remove the plating mask 21.

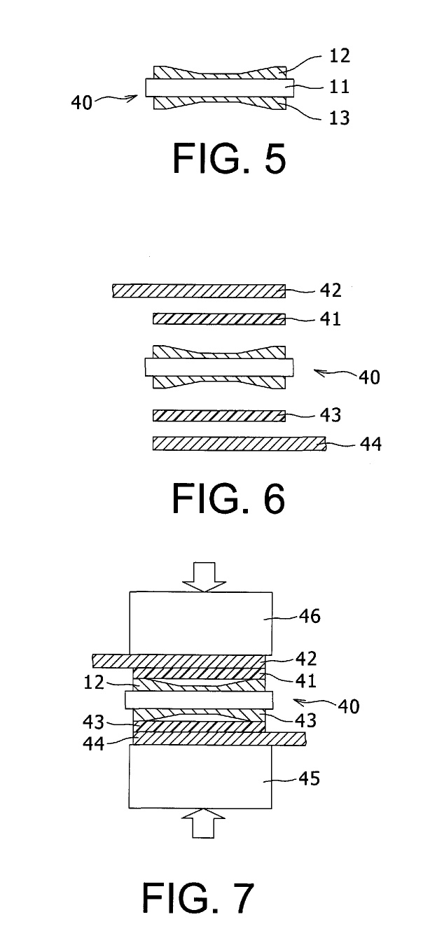

FIG. 5 is a view that illustrates a solar cell 40 from which a plating mask was removed and in which the collecting electrodes 12 and 13 were formed by electrolytic plating on the photoelectric conversion section 11. FIG. 5 corresponds to a sectional view along a line E-E in FIG. 3(a).

In the solar cell 40, the collecting electrode 12 is disposed on the light-receiving surface side of the photoelectric conversion section 11, and the collecting electrode 13 is disposed on the rear surface side. Here, the thickness of the collecting electrodes 12 and 13 in the X direction is thicker at the end portions on the photoelectric conversion section 11 than at the center portion.

Returning again to FIG. 2, after the solar cell 40 is formed in this manner (S12), next disposition of adhesive layers (S13) and disposition of wiring materials (S14) is performed. FIG. 6 illustrates the manner in which an adhesive layer 41 and wiring material 42 are disposed on the light-receiving surface side, and an adhesive layer 43 and wiring material 44 are disposed on the rear surface side of the solar cell 40.

Returning again to FIG. 2, next, a crimping process is performed (S15). A pair of crimping jigs that consist of a lower crimping jig 45 and an upper crimping jig 46 are used for the crimping process. The solar cell 40, the adhesive layers 41 and 43, and the wiring materials 42 and 44 are stacked and disposed in the order shown in FIG. 7 between the pair of crimping jigs. That is, the wiring material 44 is disposed on the lower crimping jig 45. The adhesive layer 43 is disposed on the wiring material 44, the solar cell 40 is then disposed thereon so that the collecting electrode 13 that is on the rear surface side of the solar cell 40 is on the adhesive layer 43. The adhesive layer 41 is then disposed on the collecting electrode 12 on the light-receiving surface side of the solar cell 40, and the wiring material 42 is disposed on the adhesive layer 41. The upper crimping jig 46 is disposed on the wiring material 42.

The crimping process is performed so that, in the state shown in FIG. 7, the upper crimping jig 46 is relatively pressed against the lower crimping jig 45. When the adhesive layers 41 and 43 are layers that contain thermosetting resin, pressurization and heating are performed in the crimping process. The heating is performed by incorporating a heater into the lower crimping jig 45 and the upper crimping jig 46, passing a current to the respective heaters, and controlling the lower crimping jig 45 and the upper crimping jig 46 to a predetermined temperature.

As shown in FIG. 7, on the light-receiving surface side of the solar cell 40, the thickness of the end portions of the collecting electrode 12 is thick and the thickness of the center portion is thin in the X direction. Therefore, when the wiring material 15 is pressed through the adhesive layer 14 by the crimping process, the pressing force with respect to the adhesive layer 14 is liable to rise at the end portions at which the collecting electrode 12 projects more, in comparison to the center portion. As a result, the adhesive layer 14 is more easily removed at the end portions of the collecting electrode 12 than at the center portion thereof, and consequently the thickness of the adhesive layer 14 becomes thinner at the end portions and thicker at the center portion. The same applies with respect to the rear surface side also.

Returning again to FIG. 2, in this way, formation of the adhesive layers 14 and 16 is performed by means of the crimping process so that, in the X direction, the thickness of portions that correspond to the center portions of the collecting electrodes 12 and 13 become thicker than the thickness of portions that correspond to the end portions A, B, C and D (S15), and thus the solar cell module 10 is obtained (S16).

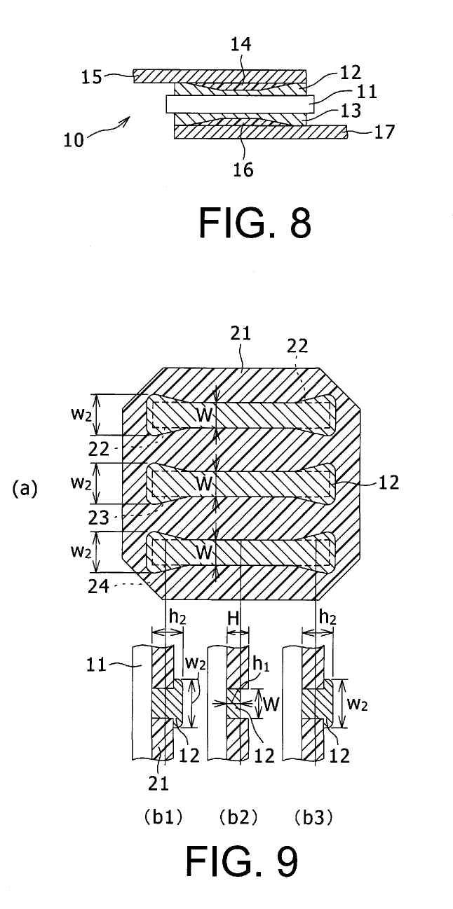

A sectional view of the solar cell module 10 after the crimping process is shown in FIG. 8. The sectional view in FIG. 8 corresponds to FIG. 1, and in FIG. 8 the wiring materials 15 and 17 are schematically illustrated as being flat. As shown in FIG. 8, in the solar cell module 10, with respect to the collecting electrodes 12 and 13, the thickness of the end portions of the collecting electrodes 12 and 13 is formed thicker than at the center portions thereof in the X direction. Further, with respect to the adhesive layers 14 and 16, portions that correspond to the center portions of the collecting electrodes 12 and 13 are formed thicker than portions that correspond to the end portions of the collecting electrodes 12 and 13 in the X direction. Thus, a structure can be formed in which, at the end portions on the photoelectric conversion section 11 at which current crowding is liable to arise in the wiring materials 15 and 17, resistance components of the adhesive layers 14 and 16 decrease, mechanical joints between the wiring materials 15 and 17 and the collecting electrodes 12 and 13 are strong, and the electrical resistance is low.

At this time, a configuration may also be adopted in which the adhesive that serves as the adhesive layer 14 is pushed out at the end portions of the photoelectric conversion section 11 and spreads as far as the side faces of the wiring materials 15 and 17 to form a fillet. As a result, the mechanical adhesive strength of the wiring materials 15 and 17 becomes stronger.

FIGS. 9(a) and (b1) to (b3) illustrate an example in which, by appropriately setting the thickness of the plating mask 21, the width of the end portions of the collecting electrode 12 can be made wider than the width of the center portion thereof in the X direction. FIG. 9(a) is a plan view of the light-receiving surface of the solar cell 40 after electrolytic plating is performed using the plating mask 21 shown in FIGS. 3(a) and (b). FIGS. 9(b1), (b2), and (b3) are a sectional view of an end portion on the left side of an opening section 24 shown in FIG. 9(a), a sectional view of a center portion of the opening section 24, and a sectional view of an end portion on the right side of the opening section 24, respectively. Here the terms “left side” and “right side” refer to the directions when the page is viewed from above. Note that the term “width of the collecting electrodes 12 and 13” refers, in the case of viewing the light-receiving surface or the rear surface of the photoelectric conversion section 11 from above, to a length in a direction that is perpendicular to the X direction in which the collecting electrodes 12 and 13 extend.

Here, a width dimension of the opening sections 22 to 24 of the plating mask 21 is denoted by “W”, and a thickness dimension is denoted by “H”. When electrolytic plating is performed, a plating thickness h₂ of the end portions of the collecting electrode 12 becomes thicker than a plating thickness h₁ of the center portion thereof. Here, the electrolytic plating conditions are set so that h₂>H>h₁. That is, formation of the collecting electrode 12 by electrolytic plating is performed until the thickness h₂ of the end portions of the collecting electrode 12 in the X direction becomes thicker than the thickness H of the plating mask 21, and so that the thickness h₁ of the center portion of the collecting electrode 12 does not exceed the thickness H of the plating mask 21. When the collecting electrode 12 is formed in this manner, a width w₁ of the center portion of the collecting electrode 12 is restricted by the width dimension W of the plating mask 21, and therefore the width w₁ is such that w₁=W. In contrast, at the end portions of the collecting electrode 12, since the plating thickness h₂ exceeds the thickness dimension H of the plating mask 21, the width w₂ of the collecting electrode 12 becomes wider than W. That is, the widths are such that w₂>W=w₁. The result is the same on the rear surface side also.

Thus, the widths of the collecting electrodes 12 and 13 can be widened at the end portions on the photoelectric conversion section 11 at which current crowding is liable to arise in the wiring materials 15 and 17. As a result, the structure is one in which the mechanical joints between the wiring materials 15 and 17 and the collecting electrodes 12 and 13 at the end portions on the photoelectric conversion section 11 are stronger, and the electrical resistance is lower.

A bright plating process and a matte plating process are available as plating processes, and enhancement of the photoelectric conversion efficiency in the solar cell module 10 can be achieved by selectively using these plating processes in a suitable manner. In particular, use of these two kinds of plating processes is effective when providing a textured structure on the surface of the solar cell 40.

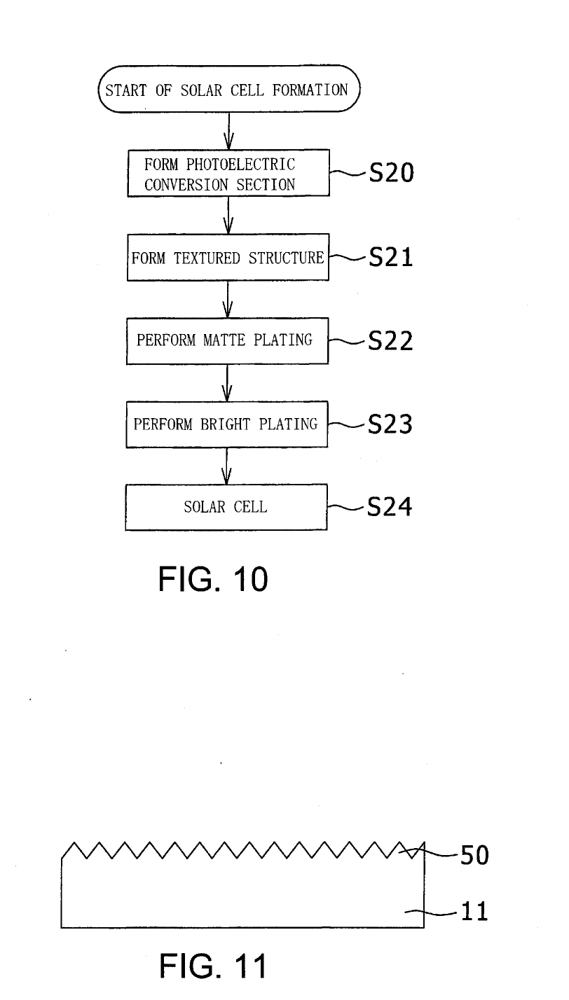

FIG. 10 is a view that illustrates the details of a plating process with respect to procedures for forming the solar cell 40 that has a textured structure. FIG. 11 to FIG. 13 are sectional views illustrating the manner in which procedures described in FIG. 10 are performed.

In this case, formation of the photoelectric conversion section 11 is performed (S20), and a textured structure is then formed on the surface thereof (S21). The contents of S20 are the same as in S10 of FIG. 2. The textured structure formed in S21 is a structure in which concavities and convexities are provided on the surface of the photoelectric conversion section 11, and consequently light that is incident on the light-receiving surface of the solar cell 40 or the like is scattered thereby. A sectional view of the photoelectric conversion section 11 in which a textured structure 50 is formed is shown in FIG. 11.

Next, formation of the collecting electrode is performed, and a matte plating method is used as the plating method (S22). The matte plating method is in contrast to the bright plating method. The bright plating method is a method in which a suitable bright material is added to the plating solution, and a deposition rate with respect to convex portions is controlled to thereby form a flat and bright metal layer. Therefore, if the bright plating method is used for forming a main layer of the collecting electrode, because the electrode surface will be flat, a light trapping effect will decrease and the photoelectric conversion efficiency will decline.

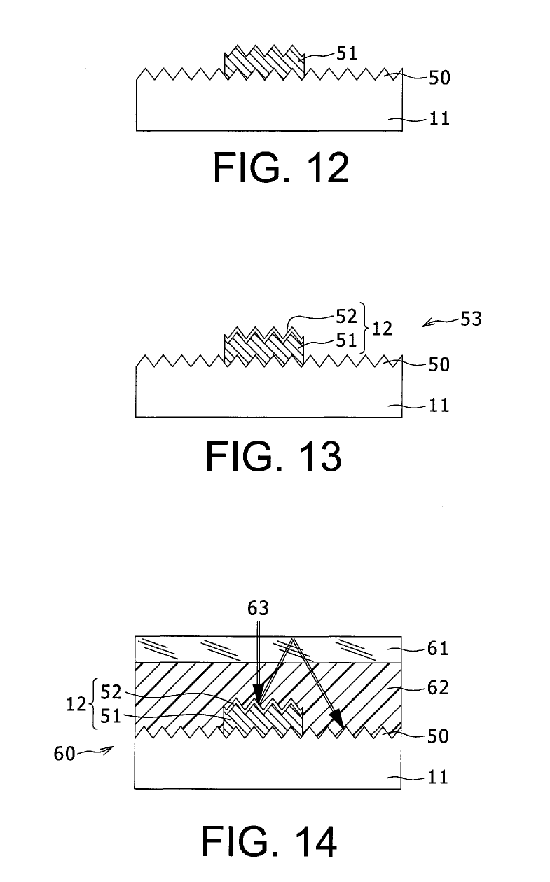

FIG. 12 is a sectional view at a time that a matte plated layer 51 is formed on the textured structure. The matte plated layer 51 formed by the matte plating method is formed in a shape that corresponds to the concavities and convexities of the textured structure 50.

To further enhance the photoelectric conversion efficiency, it is good to raise the reflectivity with respect to the concavo-convex surface. Therefore, returning again to FIG. 10, after the matte plating process, a bright plating process is performed to adjust the shape of the substrate surface (S23). FIG. 13 is a sectional view at a time that a bright plated layer 52 is formed on the matte plated layer 51 that has concavities and convexities on the surface thereof.

Since the structure in this case is one for ensuring that the concavities and convexities on the surface of the matte plated layer 51 having a high light trapping effect are left as they are, the bright plated layer that is formed here may have a thin thickness. If the metal surface of the matte plated layer 51 has a sufficient light trapping effect, the bright plating process need not be performed. A layered product in which the bright plated layer 52 is formed on the matte plated layer 51 corresponds to the collecting electrode 12 that was described above using FIG. 1 and FIG. 8. Note that although, as described with respect to FIG. 1 and FIG. 8, the thickness of the collecting electrode 12 formed by the plating method is thick at the ends and thin at the center portion in the X direction of the photoelectric conversion section 11, regardless of the thickness of the collecting electrode 12, the surface of the layered product of the matte plated layer 51 and the bright plated layer 52 has concavities and convexities that reflect the concavities and convexities of the textured structure 50.

FIG. 14 is a sectional view of a solar cell module 60 that uses a solar cell 53 formed as illustrated in FIG. 13. The solar cell 53 is a solar cell in which a collecting electrode that is constituted by the matte plated layer 51 and the bright plated layer 52 is formed on the photoelectric conversion section 11. The solar cell module 60 is formed by disposing a filler 62 between the solar cell 53 and a protective member 61 on the light-receiving surface side. A transparent plate body or film is used as the protective member on the light-receiving surface side. For example, a translucent member such as a glass plate, a resin plate or a resin film can be used. A member that is the same as the protective member on the light-receiving surface side can be used as a protective member on the rear surface side. EVA, EEA, PVB, a silicon-based resin, a urethane-based resin, an acrylic resin, an epoxy-based resin or the like can be used as the filler.

In FIG. 14, when light that passes through the protective member 61 and the filler 62 is incident on the collecting electrode 12, the light is scattered by the concavities and convexities on the surface of the collecting electrode 12. Although some of the scattered light reaches the textured structure 50 as it is, part of the scattered light travels in the direction of the protective member 61. Since the light that travels in the direction of the protective member 61 is scattered light whose directivity is not uniform due to the concavities and convexities on the surface of the collecting electrode 12, the scattered light arrives at the boundary surface between the protective member 61 and the outside air at diverse angles, and the light is totally reflected at the aforementioned boundary surface and returned in the direction of the textured structure 50.

By forming the matte plated layer 51 on the textured structure 50 in this manner, the surface thereof serves as concavities and convexities, and hence incident light can be converted to scattered light to thereby improve the photoelectric conversion efficiency of the solar cell module 60.

### REFERENCE SIGNS LIST

10, 60 solar cell module, 11 photoelectric conversion section, 12, 13 collecting electrode, 14, 16, 41, 43 adhesive layer, 15, 17, 42, 44 wiring material, 20 substrate with a plating mask, 21 plating mask, 22, 23, 24 opening section, 25, 26, 27, 28 power supply terminal, 30 plating bath, 31 plating solution, 32, 33 anode plate, 34, 35 plating power source, 40, 53 solar cell, 45 lower crimping jig, 46 upper crimping jig, 50 textured structure, 51 matte plated layer, 52 bright plated layer, 61 protective member, 62 filler

1. A solar cell module, comprising:
a photoelectric conversion section;
a collecting electrode disposed on the photoelectric conversion section;
an adhesive layer disposed on the collecting electrode; and
wiring material that is connected to the collecting electrode with the adhesive layer therebetween;
wherein:
in the collecting electrode, a thickness of an end portion of the collecting electrode is formed thicker than a center portion thereof in a longitudinal direction of the collecting electrode; and
in the adhesive layer, a thickness of a portion corresponding to the center portion of the collecting electrode is formed thicker than a thickness of a portion corresponding to the end portion of the collecting electrode in the longitudinal direction of the collecting electrode.

2. The solar cell module according to claim 1, wherein:
in the collecting electrode, a width of the end portion of the collecting electrode is wider that a width of the center portion in the longitudinal direction of the collecting electrode.

3. The solar cell module according to claim 1, wherein:
the photoelectric conversion section has concavities and convexities on a surface thereof, and
the collecting electrode has concavities and convexities on a surface thereof that correspond with the concavities and convexities on the surface of the photoelectric conversion section.

4. The solar cell module according to claim 2, wherein:
the photoelectric conversion section has concavities and convexities on a surface thereof, and
the collecting electrode has concavities and convexities on a surface thereof that correspond with the concavities and convexities on the surface of the photoelectric conversion section.

5. A method for manufacturing a solar cell module that is a method that forms a collecting electrode on a photoelectric conversion section, and connects wiring material to the collecting electrode with an adhesive layer therebetween, wherein:
a power supply section is provided at both end portions of the photoelectric conversion section in a longitudinal direction of the collecting electrode, and the collecting electrode is formed by electrolytic plating in a formation region for the collecting electrode on the photoelectric conversion section;
an adhesive is coated on the collecting electrode to form an adhesive layer;
the collecting electrode and the wiring material are connected by pressing the wiring material from above the adhesive layer;
a thickness of an end portion of the collecting electrode is formed thicker than a thickness of a center portion thereof in the longitudinal direction of the collecting electrode by electrolytic plating; and
in the adhesive layer, a thickness of a portion that corresponds to the center portion of the collecting electrode is formed thicker than a thickness of a portion thereof that corresponds to the end portion of the collecting electrode in the longitudinal direction of the collecting electrode by pressing the wiring material against the collecting electrode.

6. The method for manufacturing a solar cell module according to claim 5, wherein:
in a step of forming the collecting electrode by electrolytic plating,
a plating mask having an opening section corresponding to the formation region for the collecting electrode is disposed on the photoelectric conversion section,
formation of the collecting electrode by the electrolytic plating is performed until the thickness of the end portion of the collecting electrode in the longitudinal direction of the collecting electrode becomes thicker than a thickness of the plating mask, and
a width of a portion that is thicker than the thickness of the plating mask of the collecting electrode becomes wider than a width of the opening section of the plating mask.

7. The method for manufacturing a solar cell module according to claim 6, wherein:
formation of the collecting electrode by the electrolytic plating is performed so that the thickness of the center portion of the collecting electrode in the longitudinal direction of the collecting electrode becomes thinner than the thickness of the plating mask.

8. The method for manufacturing a solar cell module according to claim 5, wherein:
the photoelectric conversion section has concavities and convexities on a surface thereof; and
the collecting electrode is formed so as to have concavities and convexities on a surface thereof that correspond with the concavities and convexities on the surface of the photoelectric conversion section.

9. The method for manufacturing a solar cell module according to claim 6, wherein:
the photoelectric conversion section has concavities and convexities on a surface thereof; and
the collecting electrode is formed so as to have concavities and convexities on a surface thereof that correspond with the concavities and convexities on the surface of the photoelectric conversion section.

10. The method for manufacturing a solar cell module according to claim 7, wherein:
the photoelectric conversion section has concavities and convexities on a surface thereof; and
the collecting electrode is formed so as to have concavities and convexities on a surface thereof that correspond with the concavities and convexities on the surface of the photoelectric conversion section.

11. The method for manufacturing a solar cell module according to claim 8, wherein:
the collecting electrode is formed by forming a matte plated layer by a matte plating process on the formation region for the collecting electrode of the photoelectric conversion section, and forming a bright plated layer by a bright plating process on the matte plated layer.

12. The method for manufacturing a solar cell module according to claim 9, wherein:
the collecting electrode is formed by forming a matte plated layer by a matte plating process on the formation region for the collecting electrode of the photoelectric conversion section, and forming a bright plated layer by a bright plating process on the matte plated layer.

13. The method for manufacturing a solar cell module according to claim 10, wherein:
the collecting electrode is formed by forming a matte plated layer by a matte plating process on the formation region for the collecting electrode of the photoelectric conversion section, and forming a bright plated layer by a bright plating process on the matte plated layer.
